(19) United States
(12) Patent Application Publication
(10) Pub. No.: US 2008/0113520 A1
(43) Pub. Date: May 15, 2008

(54) Method of Forming Organic Layer on Semiconductor Substrate

(75) Inventor: Byung-Eun Park, Seoul (KR)

Correspondence Address: BRUCE E. LILLING;LILLING & LILLING PLLC, P.O. BOX 560, GOLDEN BRIDGE, NY, 10526, US

(73) Assignee: University of Seoul Foundation of Industry- Academic Cooperation, Seoul (KR)

(21) Appl. No.: 11/721,608

(22) PCT Filed: Sep. 7, 2006
(86) PCT No.: PCT/KR06/03552

§ 371 Date: Jun. 13, 2007

(30) Foreign Application Priority Data
Sep. 7, 2005 (KR) KR10-2005-0083205
Sep. 6, 2006 (KR) KR10-2006-0085665

(51) Int. Cl. H01L 21/31; H01L 21/469

(52) U.S. Cl. 438/780

(57) ABSTRACT

Disclosed relates to a method of coating or stacking an organic material to form an organic layer on a semiconductor substrate such as silicon, GaAs, etc. In the present invention, a polished semiconductor substrate is soaked in silanes, KOH, or a mixed solution of H2SO4 and H2O2. As a result, H-groups or OH-groups are generated on the surface of the semiconductor surface, which results in van der Waals bonding or hydrogen bonding between the semiconductor substrate and the organic material, thus forming the organic layer on the semiconductor substrate.

### TECHNICAL FIELD

The present invention relates to a method of coating or stacking an organic material to form an organic layer on a semiconductor substrate, such as silicon or GaAs, etc.

### BACKGROUND ART

In general, a semiconductor device is fabricated by forming various electrodes, wiring layers and insulating layers, made of metals or inorganic materials, on a semiconductor substrate such as silicon and the like. However, attempts aimed at fabricating semiconductor devices using environment-friendly and low cost organic materials have been made recently.

For example, in Korean Patent Application No. 10-2005-0039167 titled “Memory device using organic material and method of manufacturing the same,” a method of manufacturing a memory device using an organic material having ferroelectric characteristics has been disclosed by the present inventor and the applicant.

However, since the surface of the semiconductor substrate has a hydrophobic property in general, it is difficult to form the organic material thereon. Accordingly, there have been serious difficulties in manufacturing semiconductor devices using organic materials.

### DISCLOSURE

### Technical Problem

The present invention has been contrived taking the above circumstances into consideration and the object of the present invention is to provide a method of coating or stacking an organic material easily to form an organic layer on a semiconductor substrate.

### Technical Solution

To accomplish an object of the present invention, there is provided a method of forming an organic layer on a semiconductor substrate in accordance with a first aspect of the present invention comprising: a method of forming an organic layer on a semiconductor substrate comprising the steps of: soaking a semiconductor substrate in a surface treatment solution; drying the surface treatment solution on the semiconductor substrate; and stacking an organic material on the semiconductor substrate, the surface treatment solution inducing van der Waals bonding or hydrogen bonding between the semiconductor substrate and the organic material.

Moreover, the surface treatment solution generates H-groups on the semiconductor substrate.

Furthermore, the surface treatment solution generates OH-groups on the semiconductor substrate.

To accomplish another object of the present invention, there is provided a method of forming an organic layer on a semiconductor substrate in accordance with a second aspect of the present invention comprising: a method of forming an organic layer on a semiconductor substrate comprising the steps of: soaking a semiconductor substrate in a surface treatment solution; drying the surface treatment solution on the semiconductor substrate; and stacking an organic material on the semiconductor substrate, the surface treatment solution generating H-groups on the semiconductor substrate.

To accomplish still another object of the present invention, there is provided a method of forming an organic layer on a semiconductor substrate in accordance with a third aspect of the present invention comprising: a method of forming an organic layer on a semiconductor substrate comprising the steps of: soaking a semiconductor substrate in a surface treatment solution; drying the surface treatment solution on the semiconductor substrate; and stacking an organic material on the semiconductor substrate, the surface treatment solution generating OH-groups on the semiconductor substrate.

Moreover, the surface treatment solution includes at least one selected from the group consisting of silane, aki-silane, aryl-silane, fluorinated alkyl-silane, perfluorinated triethoxy silane, and heptadeca-fluorodecyl triethoxy silane solutions

Furthermore, the surface treatment solution is a 2-propanol solution into which KOH is saturated.

In addition, the surface treatment solution is a mixed solution of H₂SO₄ and H₂O₂.

### DESCRIPTION OF DRAWINGS

FIG. 1 is a flowchart for illustrating a method of forming an organic layer on a semiconductor substrate in accordance with a preferred embodiment of the present invention.

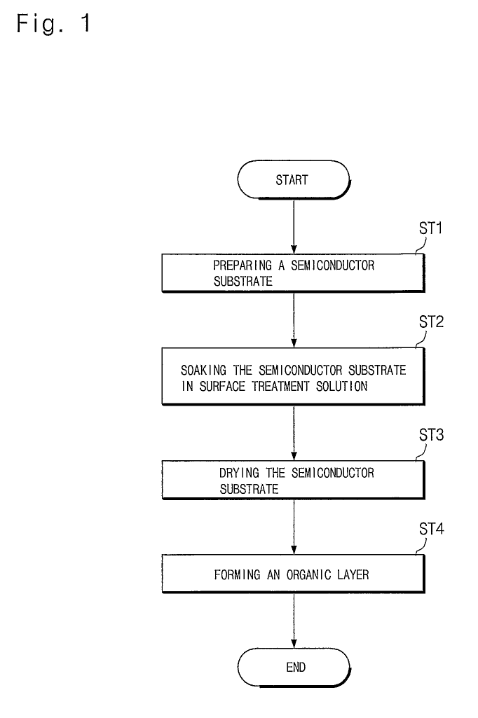

### MODE FOR INVENTION

Hereinafter, the present invention will now be described more fully with reference to the accompanying drawing, in which preferred embodiments of the invention are shown.

In general, a semiconductor substrate such as silicon, GaAs, etc. is used in fabricating a semiconductor device. Such semiconductor substrates are cut from an ingot and polished to use. In the process of polishing the semiconductor substrates cut from the ingot, since dangling bonds on the semiconductor substrates are cut and removed, the bonding force between the semiconductor substrate and the organic material applied thereto is remarkably decreased. That is, there have been problems in that the materials such as organics and the like are not coated or stacked on the semiconductor substrate.

Meanwhile, Korean Patent Application No. 10-2005-0039167 filed by the present inventor relates to a ferroelectric memory device. The patent application is directed to the use of an organic material as a ferroelectric material for manufacturing a ferroelectric memory device, preferably, a PVDF of β-phase. In general, if forming an organic layer such as PVDF and the like on the polished semiconductor substrate, it is difficult to form a thin film below a specific thickness due to the lowered bonding force between the semiconductor and the organic material as describe above. That is, the organic layer formed on the semiconductor substrate becomes thicker inevitably. The ferroelectric memory is used for materializing a non-volatile memory device using polarization characteristics of the ferroelectric layer. However, if the organic layer is formed thickly on the semiconductor substrate, it is necessary to apply a high voltage to the organic layer in order to obtain the polarization characteristics of the corresponding organic layer. That is, the high voltage is required for driving the memory device.

Accordingly, it is required to form the thin film of the ferroelectric organic layer below a specific thickness, preferably, below 1 μm in order to materialize an organic ferroelectric memory device that can operate at low voltage below a specific voltage.

The present inventor has confirmed that van der Waals bonding or hydrogen bonding is a very useful means for bonding an organic material with a semiconductor substrate. Moreover, it is desirable that H-groups or OH-groups be generated on the surface of the semiconductor substrate for the van der Waals bonding or the hydrogen bonding.

The present inventor has conducted various experiments in generating H-groups or OH-groups on the semiconductor substrate and, as a result, it is confirmed that silanes, KOH, or a mixed solution of H₂SO₄ and H₂O₂ may be used in generating H-groups or OH-groups. In more detail, silane, aki-silane, aryl-silane, fluorinated alkyl-silane, perfluorinated triethoxy silane, and heptadeca-fluorodecyl triethoxy silane solutions are useful in generating H-groups. Moreover, a 2-propanol solution into which KOH is saturated and a mixed solution of H₂SO₄ and H₂O₂ mixed in a fixed ratio are useful in generating OH-groups. Of course, as these solutions for the surface treatment, any other solutions that can generate H-groups or OH-groups on the semiconductor substrate can be used in addition to the above solutions.

Subsequently, a process of forming an organic layer on a silicon substrate, for example, using the above-described surface treatment solutions will now be described below.

First, a silicon substrate is prepared to stack an organic material thereon (ST1). Here, source and drain regions are previously provided on the silicon substrate, if necessary. Next, the silicon substrate is soaked in the above-described surface treatment solution for a predetermined period to generate H-groups or OH-groups on the surface of the silicon substrate (ST2). Then, the silicon substrate is dried with an air gun using nitrogen, for example (ST3), and an organic material is stacked on the silicon substrate to form an organic layer (ST4). Here, the general methods such as deposition, sputtering or spin coating can be used in stacking the organic material. After stacking the organic material, a specific organic layer is formed by executing etching using a photoresist, for example.

In the preferred embodiment described above, the bonding force between the silicon substrate and the organic material is noticeably increased owing to the generation of H-groups or OH-groups. Accordingly, if forming an organic layer such as a PVDF layer of β phase on a semiconductor substrate via the above-described method, it is possible to apply the general methods of deposition, sputtering, spin coating, etc. to form a PVDF thin film below 1 μm in thickness.

As described in detail above, the thickness of thin film of the organic ferroelectric layer is an important factor for determining the operation voltage of the non-volatile memory device. As a result of forming a PVDF thin film below 1 μm in thickness on a silicon substrate and measuring the voltages, at which the corresponding ferroelectric layer showed polarization characteristics, the present inventor has confirmed that the polarization characteristics are shown at voltages in the range of −1 to 1V, approximately, which means that it is possible to materialize a non-volatile memory device that operates at low voltages of −1 to 1V.

As above, the preferred embodiment of the present invention has been described. However, the above-described embodiment is one of the desirable examples of the present invention and the present invention can be embodied with various modifications within the range, not departing from the spirit and scope of the present invention.

For example, in the above-described embodiment of the present invention, the generation of H-groups or OH-groups on the semiconductor substrate has been described set limited to the use of silanes, KOH or a mixed solution of H₂SO₄ and H₂O₂. However, the present invention can use any other surface treatment solutions that can induce the van der Waals bonding or the hydrogen bonding between the semiconductor substrate and the organic material.

Moreover, as methods of stacking an organic layer on a semiconductor substrate, the present invention can apply any other stacking methods available at present in addition to the deposition, sputtering and spin coating.

Furthermore, the present invention can be applied to any other substrates used in fabricating semiconductor devices, not limited to the general silicon substrate or the GaAs substrate.

### INDUSTRIAL APPLICABILITY

As described above, the present invention can coat or stack an organic material on a semiconductor substrate easily, thus providing a technical basis for fabricating organic semiconductors more easily in the future.

1. A method of forming an organic layer on a semiconductor substrate comprising the steps of:
soaking a semiconductor substrate in a surface treatment solution;
drying the surface treatment solution on the semiconductor substrate; and
stacking an organic material on the semiconductor substrate,
the surface treatment solution inducing van der Waals bonding or hydrogen bonding between the semiconductor substrate and the organic material.

2. The method of forming an organic layer on a semiconductor substrate as recited in claim 1,
wherein the surface treatment solution generates H-groups on the surface of the semiconductor substrate.

3. The method of forming an organic layer on a semiconductor substrate as recited in claim 2,
wherein the surface treatment solution includes at least one selected from the group consisting of silane, aki-silane, aryl-silane, fluorinated alkyl-silane, perfluorinated triethoxy silane, and heptadeca-fluorodecyl triethoxy silane solutions

4. The method of forming an organic layer on a semiconductor substrate as recited in claim 1,
wherein the surface treatment solution generates OH-groups on the surface of the semiconductor substrate.

5. The method of forming an organic layer on a semiconductor substrate as recited in claim 4,
wherein the surface treatment solution is a 2-propanol solution into which KOH is saturated.

6. The method of forming an organic layer on a semiconductor substrate as recited in claim 4,
wherein the surface treatment solution is a mixed solution of H₂SO₄ and H₂O₂.

7. A method of forming an organic layer on a semiconductor substrate comprising the steps of:
soaking a semiconductor substrate in a surface treatment solution;
drying the surface treatment solution on the semiconductor substrate; and
stacking an organic material on the semiconductor substrate,
the surface treatment solution generating H-groups on the surface of the semiconductor substrate.

8. The method of forming an organic layer on a semiconductor substrate as recited in claim 7,
wherein the surface treatment solution includes at least one selected from the group consisting of silane, aki-silane, aryl-silane, fluorinated alkyl-silane, perfluorinated triethoxy silane, and heptadeca-fluorodecyl triethoxy silane solutions

9. A method of forming an organic layer on a semiconductor substrate comprising the steps of:
soaking a semiconductor substrate in a surface treatment solution;
drying the surface treatment solution on the semiconductor substrate; and
stacking an organic material on the semiconductor substrate,
the surface treatment solution generating OH-groups on the surface of the semiconductor substrate.

10. The method of forming an organic layer on a semiconductor substrate as recited in claim 9,
wherein the surface treatment solution is a 2-propanol solution into which KOH is saturated.

11. The method of forming an organic layer on a semiconductor substrate as recited in claim 9,
wherein the surface treatment solution is a mixed solution of H₂SO₄ and H₂O₂.
